(19) United States
(12) Patent Application Publication
(10) Pub. No.: US 2001/0039727 A1
(43) Pub. Date: Nov. 15, 2001

(54) MANUFACTURING METHOD FOR MULTILAYER PRINTED CIRCUIT BOARD

(75) Inventors: JUNICHIROU TERAUCHI, KAWASAKI-SHI (JP); HIDEAKI YAJIMA, KAWASAKI-SHI (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: FUJITSU LIMITED, KAWASAKI (JP)

(21) Appl. No.: 09/377,067

(22) Filed: Aug. 19, 1999

(30) Foreign Application Priority Data
Dec. 15, 1998 (JP) 10-355267

(51) Int. Cl. H01K 3/10; H05K 3/36; H05K 3/02

(52) U.S. Cl. 29/846; 29/852; 29/830; 29/849

(57) ABSTRACT

A method of manufacturing a multilayer printed circuit board, which ensures connections between vias. First, insulating sheets are attached to respective end faces of inner via holes formed through an insulating layer, and then a new insulating layer is formed on the insulating layer. Then, a circuit pattern is formed on the new insulating layer, and then each land formed on the new insulating layer at a location opposed to a corresponding one of the inner via holes is perforated by using a laser beam to have a hole continuous with an inner hole of the corresponding inner via hole. Thereafter, plating is carried out to form a build-up via for connecting between each of the lands and the corresponding inner via hole. The same process is repeatedly carried out whenever a new insulating layer is provided on the existing layers.

### BACKGROUND OF THE INVENTION

1. Field of the Invention

The present invention relates to a method of manufacturing a multilayer printed circuit board, and more particularly to a method of manufacturing a multilayer printed circuit board by superposing a build-up layer formed with a conductive circuit layer upon an insulating layer formed with via holes.

2. Description of the Related Art

Recently, electronic devices and apparatuses have been rapidly made more and more miniaturized. There is no doubt that what has enabled the miniaturization of the electronic equipment is not only development of LSI technology but also development of packaging technology for electronic components.

This packaging technology aims at enhancing packaging density of electronic components on a printed circuit board. Factors actually urging enhancement of the packaging density at present are e.g. technology of integrating electronic components into a chip including the LSI technology mentioned above, which contributes to enhancement of two-dimensional packaging density. On the other hand, three-dimensional packaging density is enhanced e.g. by a method of forming a multilayer printed circuit board having a plurality of layers laminated thereto, e.g. by using interstitial via holes (IVH), or by a build-up process.

The build-up process is a technique of fabricating a printed circuit board having a three-dimensional wiring pattern by forming on a core substrate conductive layers each forming a circuit pattern and insulating layers for insulating the conductive layers from each other, alternately one upon another.

Conventionally, in the printed circuit board fabricated by the build-up process, it is required to connect between the conductive layers, so that conductors called “vias” are formed (or embedded) in each of the insulating layers at respective predetermined locations, in a manner such that they are each held in contact with a corresponding conductive trace formed on each of adjacent conductive layers, thereby electrically connecting between the layers.

According to this method, however, it is required to form land areas for connection to corresponding vias in each conductive pattern, so that space occupied by conductive traces for connecting between components is relatively decreased, which results in reduction of component density.

To solve the above problem, there has been proposed a method (hereinafter referred to as “the conventional method”) by Japanese Laid-Open Patent Publication (Kokai) No. 7-283539, in which vias are filled with an electrically conductive material and corresponding ones of the vias are coaxially connected to each other by the electrically conductive material.

As shown in FIG. 8, a multilayer printed circuit board 1 fabricated by the conventional method is comprised of a core layer 1a, a build-up layer 1b, and a build-up layer 1c.

The core layer 1a has a core substrate 10 formed with electrically conductive inner via holes 11 to 13 embedded therein. Further, there is formed a wiring pattern including wiring traces 14, 15 on an upper surface of the core layer 1a, and a wiring pattern including wiring traces 16, 17 on a lower surface of the same.

Insulating layers 20 and 40 are formed on the respective upper and lower surfaces of the core layer 1a.

The insulating layer 20 has electrically conductive build-up vias 21 to 23 embedded therein. Further, on an upper surface of the insulating layer 20, there is formed a wiring pattern including wiring traces 24, 25.

The inner via holes 11 to 13 embedded in the core layer 1a are filled with electrically conductive materials 11a to 13a, respectively. The build-up vias 22 and 23 are formed in a manner such that the bottoms thereof are held in contact with respective upper ends of the electrically conductive materials 11a, 12a, for electrical connection therebetween.

The insulating layer 40 has build-up vias 41 to 43 embedded therein. Further, on a lower surface of the insulating layer 40, there is formed a wiring pattern including a wiring trace 44. Similarly to the build-up vias 22, 23, the build-up vias 41, 42 are electrically connected to the inner via holes 12, 13, by electrically conductive materials 12a, 13a filling the inner via holes 12, 13, respectively.

An insulating layer 30 which is formed on the upper surface of the insulating layer 20 has build-up vias 31 to 33 embedded therein. Further, on an upper surface of the insulating layer 30, there is formed a wiring pattern including wiring traces 34, 35.

The build-up vias 21 to 23 embedded in the insulating layer 20 are filled with electrically conductive materials 21a to 23a, respectively. The bottoms of the build-up vias 31 to 33 are held in contact with respective upper ends of the electrically conductive materials 21a to 23a, for electrical connection between the build-up vias 31 to 33 and 21 to 23.

An insulating layer 50 is formed on the lower surface of the insulating layer 40. The insulating layer 50 has build-up vias 51 to 53 embedded therein. Further, on a lower surface of the insulating layer 50, there is formed a wiring pattern including wiring traces 54, 55. Similarly to the relationship between the build-up vias 21 to 23 and 31 to 33, the build-up vias 52, 53 are held in contact with electrically conductive materials 42a, 43a filling the build-up vias 42, 43, respectively, for electrical connection to the build-up vias 42, 43.

The conventional method requires a process step for filling via holes embedded in an identical insulating layer with electrically conductive material before another insulating layer is laminated onto the layer. However, for instance, if the inner via hole 12 is not sufficiently filled with the electrically conductive material 12a as shown in FIG. 9, a faulty contact portion 12b or a blow hole 12c may be formed. FIG. 9 shows a portion associated with the inner via hole 12 and its neighborhood on an enlarged scale.

The faulty contact portion 12b or the blow hole 12c thus formed causes insufficient electrical connection leading to a malfunction of the product or multilayer printed circuit board, or faulty connection between the vias due to aging of the product, as a result of which the reliability of the product is lowered.

Further, when a printed circuit board is formed to have many vias therein, it is required to verify that all the via holes are sufficiently filled with electrically conductive material, which complicates the manufacturing process.

Moreover, even if all the vias have been sufficiently filled with the electrically conductive materials, surfaces of the conductive materials can be eroded during the following etching process, which causes the faulty contact portions 12b to be formed as shown in FIG. 9.

Furthermore, even when a faulty contact portion is detected after the multilayer printed circuit board is completely fabricated, it is impossible to repair the portion which is located within the inner part of the printed circuit board.

Still another problem happens when it is required to alter a circuit pattern according to a change in design. In such a case, the circuit pattern can be modified by connecting one end of a jumper cable to a via and the other end of the same to a predetermined portion of the printed circuit board. However, since the via is filled with the electrically conductive material, the jumper cable is difficult to insert into the via or solder onto the same.

### SUMMARY OF THE INVENTION

It is an object of the invention to provide a method of manufacturing a printed circuit board, which ensures positive connections between vias.

To attain the above object, the present invention provides a method of manufacturing a printed circuit board comprising the steps of forming a via hole through a insulating layer at a predetermined location; providing a film for covering respective open end of the via hole; forming a new insulating layer on the film; perforating the new insulating layer with a through hole continuous with the via hole; and connecting lands formed on the new insulating layer to the via hole, by a conductive film.

The above and other objects, features and advantages of the present invention will become apparent from the following description when taken in conjunction with the accompanying drawings which illustrate a preferred embodiment of the present invention by way of example.

### BRIEF DESCRIPTION OF THE DRAWINGS

FIG. 1 is a cross-sectional view showing an example of construction of a multilayer printed circuit board according to an embodiment of the present invention;

FIGS. 2 to 4 are enlarged partial cross-sectional views of the multilayer printed circuit board, which are useful in explaining a manufacturing process according to the embodiment;

FIGS. 5 and 6 are enlarged partial cross-sectional views of the multilayer printed circuit board, which are useful in explaining an example of a repairing method to be employed when a faulty connection is detected after completion of the FIG. 4 step;

FIG. 7 is an enlarged partial cross-sectional view of the multilayer printed circuit board, which is useful in explaining an example of a modification method to be employed when a wiring pattern is required to be changed according to a design change after completion of the FIG. 4 step;

FIG. 8 is a cross-sectional view of a conventional multilayer printed circuit board; and

FIG. 9 is an enlarged partial cross-sectional view showing a portion of the FIG. 8 multilayer printed circuit board.

### DESCRIPTION OF THE PREFERRED EMBODIMENT

The present invention will now be described with reference to the accompanying drawings.

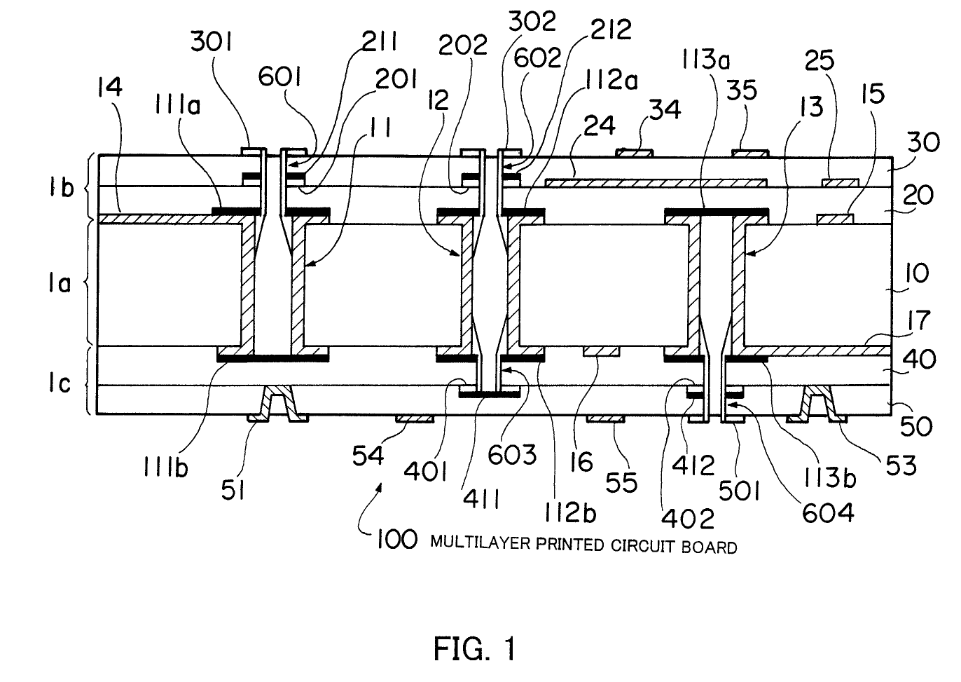

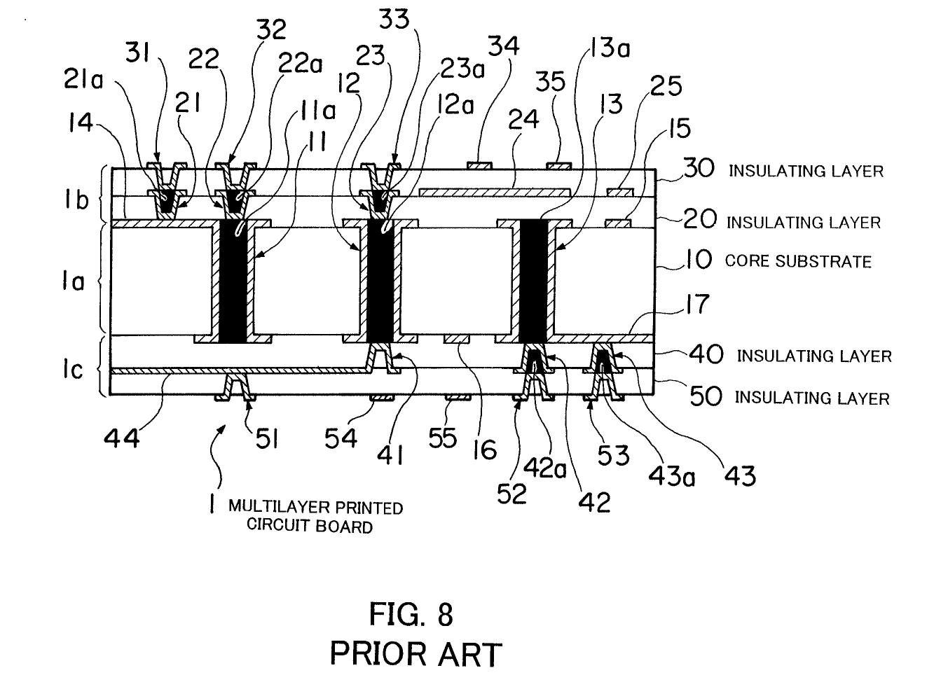

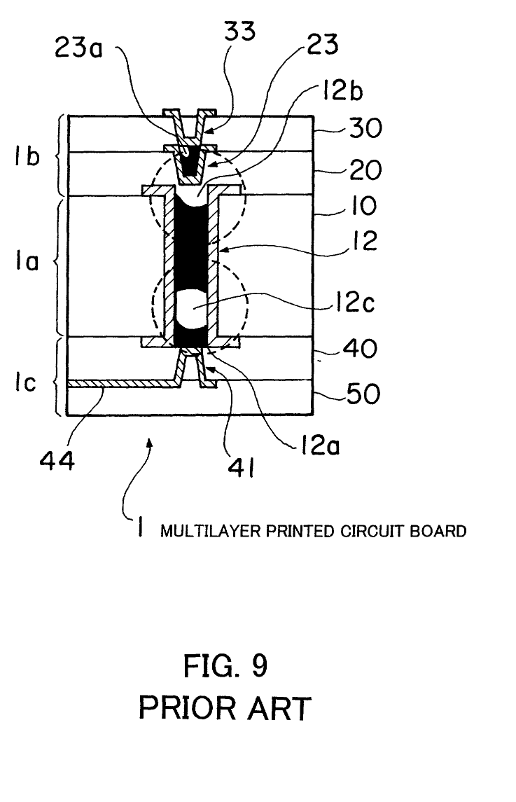

Referring first to FIG. 1, there is shown an example of construction of a multilayer printed circuit board according to an embodiment of the invention. Component parts and elements in the figure corresponding to those in FIG. 8 are designated by identical reference numerals, and detailed description thereof is omitted unless otherwise required.

As shown in FIG. 1, the multilayer printed circuit board 100 according to the embodiment is comprised of a core layer 1a, a build-up layer 1b, and a build-up layer 1c.

The core layer 1a has a core substrate 10 formed with electrically conductive inner via holes 11 to 13 extending therethough. Further, there is formed a wiring pattern including wiring traces 14, 15 on an upper surface of the core layer 1a, and a wiring pattern including wiring traces 16, 17 on a lower surface of the same.

Insulating layers 20 and 40 are formed on the upper and lower surfaces of the core layer 1a, respectively.

The insulating layer 20 has an upper surface thereof formed with a wiring pattern including lands 201, 202 forming traces for connection between vias, and wiring traces 24, 25. Each of the lands 201, 202 is e.g. in the form of a circular trace, and a build-up via, described hereinafter, is formed in contact with a central portion of the land 201 (202), for electrical connection between the layers.

On the upper surface of the insulating layer 20, there is formed an insulating layer 30. The insulating layer 30 has an upper surface thereof formed with a wiring pattern including lands 301, 302 and wiring traces 34, 35.

The inner via hole 11 embedded in the core substrate 10, the land 201 formed on the upper surface of the insulating layer 20, and the land 301 formed on the upper surface of the insulating layer 30 are electrically connected to each other by a hollow cylindrical build-up via 601 formed by plating, as described hereinafter.

The build-up via 601 is formed by two individual steps at each of which a corresponding form thereof is completed, and hence there can be a problem in dealing it as a single element. In this description, however, it is described as a single element for simplicity.

Attached to upper and lower end faces of the inner via hole 11 are insulating sheets 111a, 111b, which serve as protective caps for preventing material forming the insulating layers 20, 40 from invading the inner via hole 11 when the insulating layers 20, 40 are formed on the respective upper and lower surfaces of the core substrate 10. To connect the inner via hole 11 and the land 201 to each other by plating, a central portion of the insulating sheet 111a is melted away together with a portion of the insulating layer 20 covering the insulating sheet 111a, by using a laser beam (which will be described in detail hereinafter).

The inner via hole 12 embedded in the core substrate 10, the land 202 formed on the upper surface of the insulating layer 20, and the land 302 formed on the upper surface of the insulating layer 30 are electrically connected to each other via a hollow cylindrical build-up via 602 formed by plating.

Further, the inner via hole 12, and a land 401 formed on a lower surface of the insulating layer 40 are connected by a build-up via 603, while the inner via hole 13, a land 402 formed on the lower surface of the insulating layer 40, and a land 501 formed on a lower surface of an insulating layer 50 are connected by a build-up via 604.

Next, description will be made of the method of manufacturing the multilayer printed circuit board having the above structure.

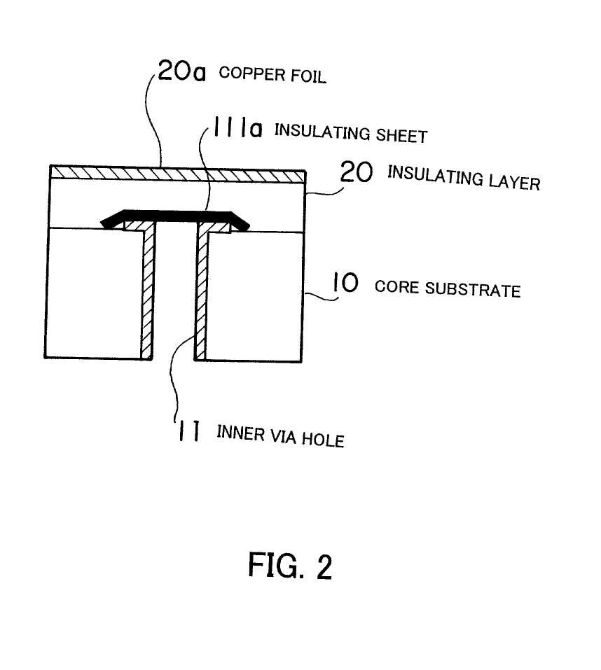

FIGS. 2 to 4 illustrate an example of a process for forming a portion of the multilayer printed circuit board related to the inner via hole 11 appearing in FIG. 1.

First, as shown in FIG. 2, the insulating sheet 111a is affixed to an end face (open end) of the inner via hole 11 to be machined. This insulating sheet 111a is formed e.g. of a polyester film having an adhesive or the like applied to one surface thereof.

The insulating sheet 111a is required to be placed upon the inner via hole 11 in a state of a surface thereof being held as smooth and flat as possible. This state of the insulating sheet 111a makes it possible to prevent the upper surface of the insulating layer 20 formed on the sheet 111a from becoming not flat. Therefore, it is preferable that the insulating sheet is formed of a material which is difficult to bend.

Further, an electrically conductive sheet can be employed in place of the insulating sheet. However, the use of the electrically conductive sheet may cause a short circuit in a circuit pattern, so that it is preferable to use the insulating sheet.

After the insulating sheet 111a has been attached to the end face of the inner via hole 11, the insulating layer 20 is formed on the upper surface of the core substrate 10. Then, a copper foil 20a to be processed into a predetermined circuit pattern is formed on the upper surface of the insulating layer 20. Thus, a multilayer printed circuit board having a cross section shown in FIG. 2 is produced.

Subsequently, the copper foil 20a is etched into the predetermined circuit pattern. As a result, the land 201 is formed exactly above the inner via hole 11. The land 201 is formed with a hole made by the etching, which is identical in shape to a through hole to be made through the insulating layer 20.

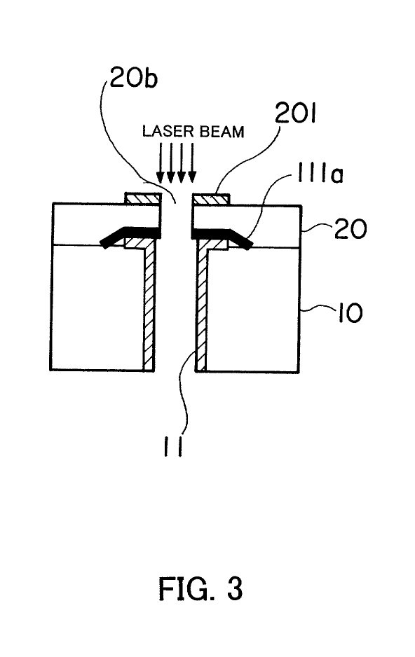

Then, as shown in FIG. 3 the portion of the insulating layer 20 exactly above the inner via hole 11 and the central portion of the insulating sheet 111a are melted by irradiation with a laser beam, whereby a through hole 20b continuous with an inner hole of the inner via hole 11 is formed.

The through hole 20b may be formed not by the laser beam but by using machining means such as a drill.

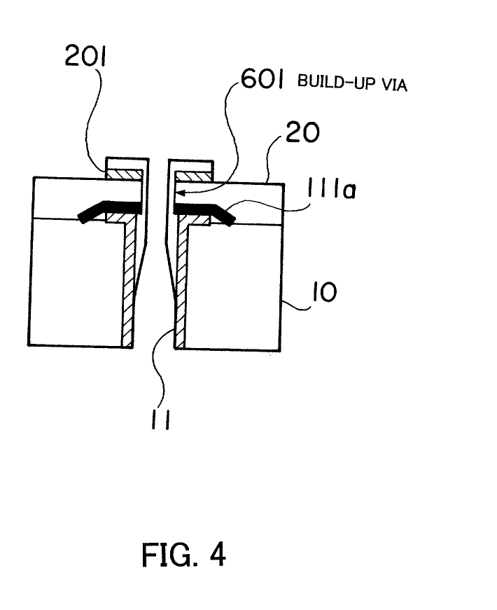

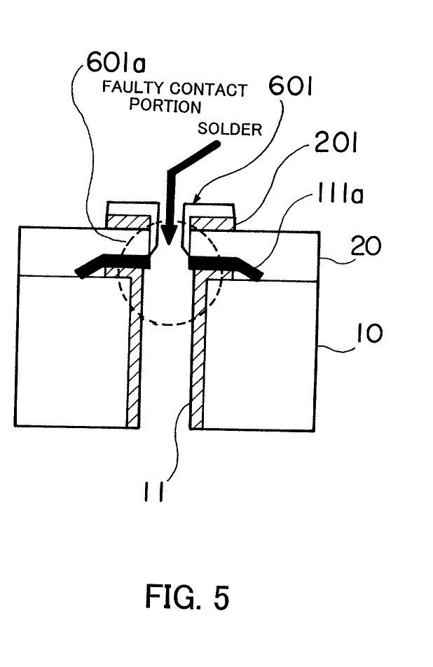

Thereafter, as shown in FIG. 4, the multilayer printed circuit board formed with the through hole 20b is subjected to plating (e.g. electrolytic copper plating), whereby an electrically conductive film (e.g. a copper film) is formed for connection between the land 201 formed on the insulating layer 20 and the inner via hole 11.

In this example, an upper surface of the land 201, an inner peripheral surface of the through hole 20b, and an inner peripheral surface of the inner via hole 11 are coated with the copper film which serves as the build-up via 601.

It is also possible to connect between build-up vias by repeatedly carrying out the above process. More specifically, after an insulating sheet 211 is attached to an end face of the build-up via 601 formed through the insulating layer 20, the insulating layer 30 is provided, and then the land 301 formed on the insulating layer 30 and the build-up via 601 shown in FIG. 4 are connected to each other by plating. As a result, the build-up via 601 appearing in FIG. 1 is formed for electrically connecting the inner via hole 11, the land 201 on the insulating layer 20, and the land 301 on the insulating layer 30 to each other as shown in the figure.

Now, let it be assumed that when the step illustrated in FIG. 4 is completed, the build-up via 601 is formed to be not properly formed by some cause and have a faulty contact portion 601a.

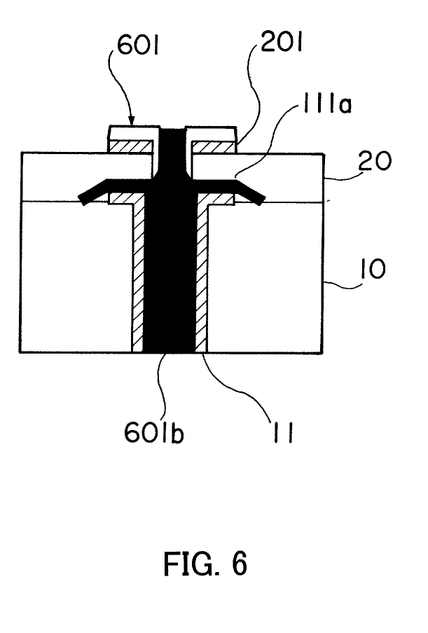

In this case, it is possible to pour an electrically conductive metal, such as solder, into the build-up via 601 to thereby repair the faulty contact portion, as shown in FIG. 6.

It should be noted that copper paste, etc. can be used for this purpose instead of the solder.

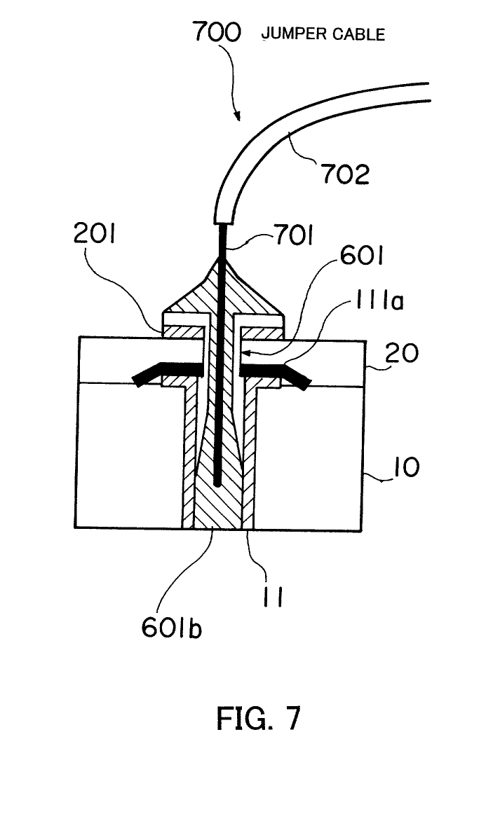

Further, if a circuit pattern is required to be altered e.g. due to a change in design, it is possible to insert a jumper cable 700 into the build-up via 601 and then pour solder or the like into the same for connection between the jumper cable 700 and the build-up via 601, as shown in FIG. 7. In the illustrated example, a wire 701 which is made bare by removing a cable sheath or coating from the jumper cable 700 is inserted into the build-up via 601, and then solder 601b is poured into the build-up via 601 for the connection.

As described above, the embodiment of the present invention enables electrical connection between the vias without filling the vias with electrically conductive material, thereby making it possible to reduce incidence of faulty connections between the vias. Further, according to the embodiment, since it is possible to dispense with a step of verifying whether the vias are completely filled with conductive material, the overall manufacturing process can be simplified.

Further, since the corresponding vias are coaxially connected to each other, space occupied by the lands in the wiring pattern on each of the insulating layers can be made smaller, which makes it possible to further enhance the packaging density of components on the multilayer printed circuit board.

Moreover, even when a faulty contact portion is formed by some cause, the portion can be repaired easily by using solder, etc. This makes it possible to enhance the yield of the product as well as reduce manufacturing costs.

Still further, a jumper cable can be connected to a via with ease, which makes it possible to alter a wiring pattern flexibly in accordance with a design change.

Additionally, since insulating sheets are attached to respective inner via holes embedded in an identical insulating layer before a new insulating layer is formed on the insulating layer, the material forming the new insulating layer is prevented by the insulating sheets from invading the via holes to make the surface of the new insulating layer concave to an extent corresponding to an amount of the invasion of the material, thereby making the surface of the insulating layer smooth and flat. As a result, it is possible to prevent faulty mounting of components due to warpage or unevenness of the surface of the insulating layer, thereby enhancing the yield of the product.

Although in the above embodiment, as shown in FIGS. 3 and 4, the wiring pattern is formed first, and then perforation is carried out by using the laser beam to form the build-up via, this is not limitative, but it is possible to first carry out the perforation by using the laser beam to form the build-up via, and then finally form the wiring pattern.

As described above, according to the present invention, the method of manufacturing a multilayer printed circuit board by repeatedly carrying out a process of forming a circuit pattern on an insulating layer formed with via holes comprises the steps of forming the via holes through the insulating layer at predetermined locations; providing films for covering respective open ends of the via holes; forming a new insulating layer on the films; perforating the new insulating layer with through holes such that each of the through holes is continuous with a corresponding one of the via holes; and connecting lands formed on the new insulating layer to corresponding ones of the via holes, by respective conductive films. Therefore, incidence of faulty connections between vias can be reduced, and at the same time, the overall manufacturing process can be simplified.

Further, even when a faulty contact portion is formed by some cause, the portion can be repaired easily, and in the event of any change in design, a wiring pattern can be altered flexibly.

Moreover, the invention makes it possible to hold the surface of each insulating layer smooth and flat, thereby preventing faulty mounting of components on the printed circuit board.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of manufacturing a printed circuit board comprising the steps of:
forming a via hole through a insulating layer at a predetermined location;
providing a film for covering respective open end of said via hole;
forming a new insulating layer on said film;
perforating said new insulating layer with a through hole continuous with said via hole; and
connecting lands formed on said new insulating layer to said via hole, by a conductive film.

2. A method of manufacturing a printed circuit board, according to claim 1, wherein said film is each in the form of an insulating sheet which is adhered to a corresponding of said respective open end of said via hole to cover said corresponding one of said respective open end.

3. A method of manufacturing a printed circuit board, according to claim 1, wherein said respective conductive film is formed by plating.
